(19) United States
(12) Patent Application Publication
(10) Pub. No.: US 2008/0283115 A1
(43) Pub. Date: Nov. 20, 2008

(54) Solar Battery Module and Photovoltaic Generation Device

(76) Inventors: Yuko Fukawa, Mie (JP); Kenji Fukui, Shiga (JP)

Correspondence Address: HOGAN & HARTSON L.L.P., 1999 AVENUE OF THE STARS, SUITE 1400, LOS ANGELES, CA, 90067, US

(21) Appl. No.: 10/597,471

(22) PCT Filed: Jan. 28, 2005
(86) PCT No.: PCT/JP2005/001631

§ 371 Date: Aug. 7, 2008

(30) Foreign Application Priority Data
Jan. 28, 2004 (JP) 2004-020289

(51) Int. Cl. H01L 31/042

(52) U.S. Cl. 136/246

(57) ABSTRACT

A solar cell module, comprising a front surface member 1 having translucency, a rear surface member 5, an intermediate member 7 formed of an insulator disposed between the front surface member 1 and the rear surface member 5, a first solar cell element group 8a disposed between the front surface member 1 and the intermediate member 7 with its light receiving surface facing the front surface member 1, and a second solar cell element group 8b disposed between the rear surface member 5 and the intermediate member 7 with its light receiving surface facing the rear surface member 5. Accordingly, light incident on both surfaces can be effectively utilized for power generation by a simple structure. The solar cell module thus provided can increases a power generating efficiency per unit area, is less affected by the surrounding adverse environment, and is adapted to the environment in which the module is installed.

### TECHNICAL FIELD

The present invention relates to a solar cell module in which a plurality of solar cell elements are connected and disposed, and a photovoltaic device using the solar cell module.

### BACKGROUND ART

A solar cell element is often made with a single crystal silicon substrate or a polycrystalline silicon substrate.

As a consequence, the solar cell element is vulnerable to physical impact, and needs to be protected from rain and the like when the solar cell element is installed outdoors.

Furthermore, since a single solar cell element generates only a small electrical generating power, a plurality of solar cell elements needs to be connected in series-parallel in order to extract practical electrical generating power.

As a consequence, a solar cell module is generally made by connecting a plurality of solar cell elements in series-parallel, installing such solar cell element group between a front surface member having translucency and a rear surface member, then enclosing it with a filler that uses an ethylene-vinyl acetate copolymer and the like as its principal component.

Furthermore, there is a solar cell module in which a lighting effect can be obtained by using a rear surface member having translucency, thus the gap between adjacent solar cell elements becomes a photic part and permeates solar light (e.g., cf. Japanese Unexamined Patent Publication No. 2001-189469).

FIG. 8 is a sectional view which shows an example of the structure of a conventional solar cell module. Reference numeral 11 denotes a front surface member, 12 denotes a light receiving surface side filler, 13 denotes a solar element, 14 denotes a rear surface side filler, 15 denotes a rear surface member, and 16 denotes an inner lead that connects the solar cell elements.

The solar cell element 13 is, for example, made with a single crystal silicon or a polycrystalline silicon having approximately 0.3 to 0.4 mm of thickness and approximately 100 to 150 mm square in size. On each surface of the solar cell element, a light receiving surface side electrode (not shown) and a rear surface side electrode (not shown) for extracting respective power outputs are formed.

A screen-printing method is used in the formation method of such electrodes, generally for the sake of low costs, printing silver paste on the surface of the solar cell element 13, and baked by burning.

When the solar cell elements are to be series-connected, the inner lead 16 which is attached to the light receiving surface side electrode of a single solar cell element is connected to a non-light-receiving surface side electrode of another adjacent solar cell element, then such procedure is repeated, as shown in FIG. 8.

The connection of inner lead 16 is conducted by fusion using a heated solder. Generally, the inner lead is made by coating the entire surface of a copper foil having approximately 0.1 to 0.3 mm of thickness with a solder.

A material having translucency, for example a glass is suitable for the front surface member 11, and a weather-resistant resin such as polyethylene terephthalate (PET) is used for the rear surface member 15.

Furthermore, EVA and polyvinyl butyral are mainly used for the light receiving surface side filler 12 and the rear surface side filler 14.

The solar cell module is made by setting a laminated material which is laminated in the order of the front surface member 11, the light receiving surface side filler 12, the solar cell element 13 connected with the inner lead 16, the rear surface side filler 14, and the rear surface member 15 to a device called a laminator, then heating and pressing under decompression to integration.

Since the conventional solar cell module generates only a small electrical generating power per unit area, the solar cell module upsizes and requires a large installation area in order to obtain the needed electric power. However, an installable area on the ground or on a roof of a building is restricted, and therefore electric power generation provided per single solar cell module needs to be increased.

Consequently, a configuration that increases electric power generation per solar cell element is disclosed in Japanese Unexamined Patent Publication No. 2002-111035, using a double-sided power generation type solar cell element, generating power not only with incident light from the front surface side but also with reflected light from the rear surface member 15.

However, making such double-sided power generation type solar cell element raised problems in which processes became complicated and resulted in high-cost in comparison to the conventional solar cell element.

In addition, solar cells come into use for various purposes, and demands to install a solar cell module in more places increase. However, the state of solar radiation where respective solar cell module is installed varies drastically due to existence of shadows from the surrounding building structures and the like. Thus, in order to obtain a necessary and sufficient electric power as much as possible for the purpose of use, a solar cell module that is less affected by adverse effects of the surrounding environment and is adapted to the environment in which the module is installed is desired.

An object of the present invention is to provide a solar cell module with a simple structure, increases power generating efficiency per unit area by effectively using light incident on both surfaces for power generation, less affected by adverse effects of the surrounding environment, and can adapt to the environment in which the module is installed.

Furthermore, an object of the present invention is to provide a photovoltaic device that enables efficient use at maximum output power of a group of respective solar cell elements of the above-mentioned solar cell module.

### DISCLOSURE OF INVENTION

A solar cell module in accordance with the present invention comprises a front surface member having translucency, a rear surface member, intermediate member formed of an insulator disposed between the front surface member and the rear surface member, a first solar cell element group in which a plurality of single-sided photoreceptor type solar cell elements are electrically connected, disposed between the front surface member and the intermediate member with its light receiving surface facing the front surface member, and a second solar cell element group in which a plurality of single-sided photoreceptor type solar cell elements are electrically connected, disposed between the rear surface member and the intermediate member with its light receiving surface facing the rear surface member.

By such configuration, the solar light incident from the front surface member side is received by the first solar cell element group, and the solar light incident from the rear surface member side is received by the second solar cell element group, enabling to effectively convert the solar light incident from various directions to electric power.

Furthermore, it becomes possible to suppress the problem in which electrical power generation changes due to the direction of installation or time, since the solar cell module is less affected by the adverse effect of the elevation angle of the sun.

As described above the solar light received from both surfaces of the solar cell module can be effectively contributed for the power generation with a simple configuration.

The present solar cell module can reduce the adverse effect from the surrounding environment and effectively exert its effects, at any given place where the solar cell module is installed, for example a sound abatement shield, a fall prevention fence, or a road sign which are set up at a roadside, an illuminating lamp or a monument which are set up at a park or the like, a wall surface or a roof of a building, a roof of a house, or on the ground.

In regard with the first solar cell element group and the second solar cell element group, it is preferable that both solar cell element groups are made up of the plurality of solar cell elements connected in series, and that both solar cell element groups are electrically insulated through the intermediary of the intermediate member. Thereby, maximum output characteristics can be drawn from both the front and the rear of the solar cell module, and by insulating the first solar cell element group and the second solar cell element group and extracting the power output separately, a loss of power output can be prevented.

In particular, in a case where the present solar module is not used alone, but when a plurality of solar cell modules are connected forming an array and used for a solar cell system, the first solar cell element group may be connected to a first solar cell element group of a different solar cell module, and the second solar cell element group may be connected to a second solar cell element group of a different solar cell module, and eventually be connected to a power conditioner. Hence, power outputs that are obtainable from the first solar cell element group and the second solar cell element group can be utilized without a loss, and effectively exert its effects of the solar cell module in regard to the present invention.

In the case where the rear surface member is a material having translucency, a direct solar light (light that reaches directly without reflection nor diffusion within the module) from the rear side of the solar cell module can be utilized. When such solar cell module is used at a place where the direction of installation is limited and assumed to face various directions, for example a sound abatement shield or a fall prevention fence at a roadside, it can further be less affected from the surrounding environment, and obtain high output characteristics that are not obtained with the conventional single-sided photoreceptor type solar cell module. Furthermore, when the solar cell module is installed in a uniform space on a wall surface or a roof of a building, it can receive the light reflected by the wall surface or the roof of the building from the rear surface side of the solar cell module, and utilize for power generation.

In the case where the rear surface member in regard to the solar cell module in accordance with the present invention is configured with a material having translucency, the intermediate member having a material that reflects light is better. By such configuration, the permeation of light incident from both front and rear surfaces can be prevented, and can reflect the light to the solar cell element side, thus enhance the output characteristics of the solar cell element, and obtain a highly efficient solar cell module. Such module exerts its effect particularly effectively when utilized as a solar cell module to be installed at a place that receives direct solar light from both sides, for example a sound abatement shield or a fall prevention fence at a roadside.

Furthermore, the intermediate member to be used for the solar cell module in accordance with the present invention may be a material having translucency. By such configuration, in a case where the material having translucency is also used in the rear surface member, it becomes possible to permeate the light incident on the solar cell module but yet did not contribute to power generation, and utilize the solar cell module as a wall surface or a lighting window. Since the light incident from the front surface member side but yet did not contribute to power generation of the first solar cell element group can be permeated to the exterior of the solar cell module, reflected by the material at the rear side and then captured into the solar cell module, the permeated light of the solar cell module can be utilized for power generation of the second solar cell element group. Such module exerts its effect particularly effectively when installed at a place that receives a strong reflected light from the exterior, for example when installed in a uniform space on a wall surface or a roof of a building.

Furthermore, the rear surface member may be a material that reflects light. By such configuration, it becomes possible for the light incident from the front surface member side but yet did not contribute to the power generation of the first solar cell element group and permeated through the solar cell module to be reflected at the rear surface member, and becomes a light incident from the light receiving surface side of the second solar cell element group, enabling power generation. Such module exerts its effect particularly effectively when installed at a place that receives light directly from the rear surface side or does not often receive reflected light from the exterior of the module, such as a flat-roof type module.

In the case where unevenness is provided to the rear surface member, light can be effectively contained by multiple reflection or the like due to the unevenness, thus enhancing the power generating efficiency more effectively.

In particular, in a case where the intermediate member has translucency, and when the solar cell element comprising the first solar cell element group and the solar cell element comprising the second solar cell element group are disposed symmetrically with the intermediate member as the reference position, the light incident to the solar cell module but yet did not contribute to power generation can be permeated, making the solar cell module preferable as a wall surface or a lighting window of a building.

Furthermore, in a case where the intermediate member has translucency, and when the solar cell element comprising the first solar cell element group and the solar cell element comprising the second solar cell element group are disposed unsymmetrically with the intermediate member as the reference position, the light incident to the solar cell module but yet did not contribute to power generation would be less permeable through the solar cell module, making the solar cell module preferable when desired to block the light.

A photovoltaic device in accordance with the present invention comprises a first solar cell string having connected the first solar cell element group, and a second solar cell string having connected the second solar cell element group, and has a power conversion means for converting direct-current power to alternating-current power as well as controlling so that direct-current power is output at the maximum power point of these first and second solar cell string, and a voltage adjustment means for adjusting direct-current voltage that is output from the second solar cell string and supplying the voltage between the first solar cell string and the voltage adjustment means, wherein the voltage adjustment means adjusts the output voltage of the second solar cell string so that it coincides with the output voltage of the first solar cell string.

The voltage adjustment means may adjust the direct-current voltage that is output from the second solar cell string based on the voltage which is to be the maximum electric power of the second solar cell string to coincide with the output voltage of the first solar cell string.

The first solar cell string denotes the inter connected first solar cell element groups of the solar cell module when a single or a plurality of solar cell modules are used, and the second solar cell string denotes that the interconnected second solar cell element groups of the solar cell module when a single or a plurality of solar cell modules are used.

The power conversion means conducts an MPPT control (Maximum Power Point Tracking) in regard to the connected solar cell string, and obtains the maximum output voltage of the solar cell string.

The step-up voltage ratio of the voltage adjustment means is automatically adjusted based on the output voltage of the first solar cell string which is the control voltage of the power conversion means and the input voltage provided from the second solar cell string.

Hence, by providing a voltage adjustment means which adjusts the direct-current voltage output from the second solar cell string in between the first solar cell string and the power conversion means, and adjusting the output voltage of the second solar cell string to coincide with the output voltage side of the first solar cell string using this voltage adjustment means, namely adjusting the output voltage of the second solar cell string to coincide with the output voltage of the first solar cell string, in a case where a solar cell module is interconnected to a commercial electric power system through the intermediary of a connection box, it enables to utilize the sum of the maximum output power from respective solar cell string as the maximum output power, even when the first solar cell string and the second solar cell string that differs in its power generating ability are included, enabling the photovoltaic device to interconnect to a commercial electric power system.

Furthermore, the voltage adjustment method only needs to be connected to the second solar cell string, and needs not to be connected to the first solar cell string.

In addition, the present invention can provide a excellent photovoltaic device that can obtain a true maximum output power even when the maximum power point of respective solar cell string differs due to a difference in installation conditions of the solar cell string, for example in a case where amount of insolation varies with each solar cell string.

Furthermore, the voltage adjustment means may have both step-up and step-down voltage adjustment functions. For example, in a case where the device has a second solar cell string in which power output falls in certain time, a step-down voltage adjustment is usually conducted. However, it is possible to conduct the step-up voltage adjustment at a target zone and extracting electric power of a solar cell string that cannot contribute to power generation by a step-down voltage adjustment alone, which enables not only increase of the generated energy but also install of a photovoltaic device in a place where it is conventionally unable to satisfy the installation condition.

### BRIEF DESCRIPTION OF DRAWINGS

FIG. 1 is a sectional view showing one embodiment of a solar cell module in accordance with the present invention.

FIG. 2 is a sectional view showing another embodiment of a solar cell module in accordance with the present invention.

FIG. 3 is a block diagram for schematically explaining one embodiment of a photovoltaic device in accordance with the present invention.

FIG. 4 is a graph indicating a relationship between generated outputs output from two solar cell strings that vary in power output ability, and a relationship of a voltage provided to a power conditioner in a conventional art.

FIG. 5 is a graph indicating a relationship between generated outputs output from two solar cell strings that vary in power output ability, and a relationship of a voltage provided to a power conditioner in the present invention.

FIG. 6 is a block diagram schematically showing an example of a voltage adjustment method included in the photovoltaic device in FIG. 3.

FIG. 7 is a flow chart showing the step-up voltage control action of the control part.

FIG. 8 is a sectional view showing a conventional solar cell module.

### BEST MODE FOR CARRYING OUT THE INVENTION

Hereinafter, embodiment of the present invention will be described in detail with reference to the accompanying drawings.

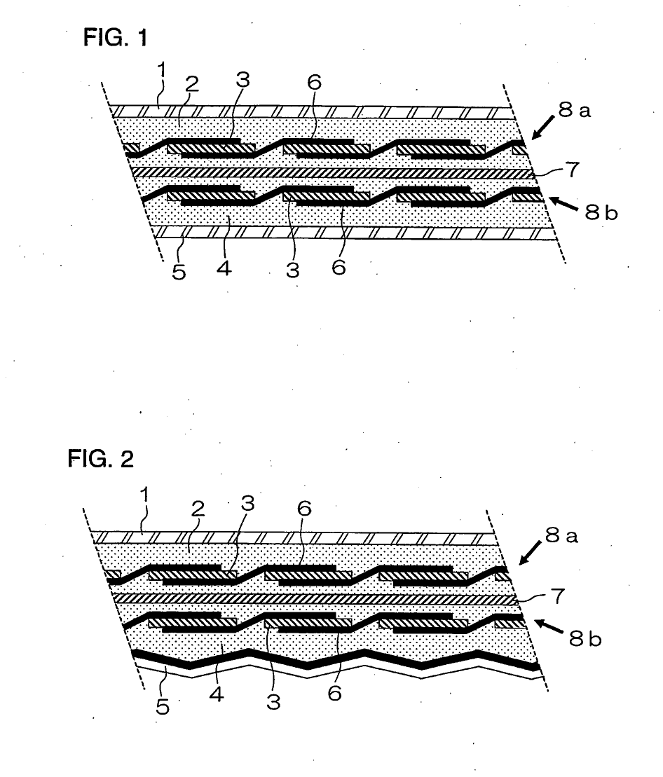

FIG. 1 is a schematic view showing a cross section structure of a solar cell module in accordance with the present invention.

In FIG. 1, 1 denotes a front surface member, 2 denotes a light receiving surface side filler, 3 denotes a single-sided photoreceptor type solar cell element, 4 denotes a rear surface side filler, 5 denotes a rear surface member, and 6 denotes an inner lead.

An intermediate member 7 exists between the front surface member 1 and the rear surface member 5. A first solar cell element group 8a is installed between the front surface member 1 and the intermediate member 7, and the light receiving surface side filler 2 is enclosed. A second solar cell element group 8b is installed between the intermediate member 7 and the rear surface member 5, and the rear surface side filler 4 is enclosed.

In regard to the front surface member 1, a member having translucency is used. Furthermore, in order to ensure the strength of the solar cell module, a hard member composed of glass or rigid plastic or the like is generally used.

In regard to the glass, a white glass, a tempered glass, a double tempered glass, or a heat reflecting glass is used, but in general, a white glass having approximately 3 to 5 mm of thickness is used. On the other hand, in a case where a substrate composed of a synthetic resin such as rigid plastic or the like is used, a member having approximately 5 mm of thickness is vastly used. Furthermore, in a case where strength is not needed in particular, or where strength can be ensured in other parts, for example by attaching on a tile, a soft member such as PET or resin or the like may be used. Either way, it is preferable to select a member having a high optical transparency since there is a need to incident light that reached the solar cell module to the solar cell element effectively.

The light receiving surface side filler 2 and the rear surface side filler 4 are generally composed of an ethylene-vinyl acetate copolymer (Hereinafter abbreviated as EVA), and a sheet-shaped form having approximately 0.4 to 1.0 mm of thickness is used

The above-mentioned members are fusion bonded to integrate with other members through heating and pressing under decompression by a laminator. EVA may be colored by including titanium oxide or pigment or the like. However, since the amount of light incident to the solar cell element decreases and electrical power generation decreases when the EVA is colored, it is desirable that the EVA is transparent.

The solar cell element 3 is composed of a single crystal silicon or a polycrystalline silicon having approximately 0.3 to 0.4 mm of thickness and approximately 100 to 150 mm square in size. There are a N-type region and a P-type region inside this solar cell element 3, and a semiconductor junction is formed at the interface portion between the N-type region and the P-type region. A light receiving surface side electrode (not shown) and a rear surface side electrode (not shown) is formed on its light receiving surface side and the rear surface side.

The inner lead 6 electrically interconnects the solar cell elements 3. A copper foil having approximately 100 to 300 μm of thickness, of which the entire surface is coated with approximately 20 to 70 μm of solder, is cut in a predetermined length, the inner lead 6 is attached to the electrode of the solar cell element 3 by heat fusion, for example a hot air.

For example, when the solar cell elements 3 are to be connected in series, the inner lead 6 which is attached to the light receiving surface side electrode of a single solar cell element is connected to a non-light-receiving surface side electrode of another adjacent solar cell element to make a solar cell element group 8, as shown in FIG. 1.

Two solar cell element groups 8 is made in this manner, and one denotes a first solar cell element group 8a, and the other denotes a second solar cell element group 8b.

The rear surface member 5 is provided so as to prevent intrusions such as moisture from the rear surface of the solar cell module and ensure long-term reliability and insulation characteristics. For example, a laminated sheet in which an aluminum foil is interposed between sheets of polyvinyl fluoride resin (Hereinafter abbreviated as PVF) or PET interposed between sheets of PVF is generally used. Furthermore, a transparent member composed of glass or rigid plastic for use in the front surface member 1 may be used. The intermediate member 7 is provided so as to insulate the first solar cell element group 8a and the second solar cell element group 8b, and EVA, PET, or materials for use in the rear surface member 5 is used.

The solar cell module is made by setting a laminated material which laminates the front surface member 1, the light receiving surface side filler 2, the first solar cell element group 8a, the intermediate member 7, the second solar cell element group 8b, the rear surface side filler 4, and the rear surface member 5 to a laminator, then heating and pressing under decompression to integration.

Parenthetically, although not shown in FIG. 1, a terminal box for extracting the power output to the exterior is generally provided at the rear surface of a solar cell module, and a bipolar terminal of an inner lead which connects a solar cell element is connected into this terminal box. Furthermore, a bipolar connecting cable is drawn out from the terminal box, and by connecting this connecting cable to a connection cable of another solar cell module, solar cell modules are interconnected and forms a solar cell array to obtain the necessary electric power for its purpose.

The solar cell module in accordance with the present invention which is configured comprises a front surface member 1 having translucency, a rear surface member 5, an intermediate member 7 formed of an insulator disposed between the front surface member 1 and the rear surface member 5, a first solar cell element group 8a in which a plurality of solar cell elements 3 are electrically connected, disposed between the front surface member 1 and the intermediate member 7 with its light receiving surface facing the front surface member 1, and a second solar cell element group 8b in which a plurality of solar cell elements are electrically connected, disposed between the rear surface member 5 and the intermediate member 7 with its light receiving surface facing the rear surface member 5.

In regard to the solar cell element 3 to be connected in series and comprising the solar cell element group 8, it is desirable to use an element having a similar power output rank which can obtain an approximately equivalent output characteristics.

By such configuration, the solar light incident from the front surface member side is received by the first solar cell element group 8a, and the solar light incident from the rear surface member 5 side is received by the second solar cell element group 8b, enabling to effectively convert the solar light into electric power.

The conventional single-sided photoreceptor type solar cell module primarily intends to receive solar light effectively by installing the light receiving surface of the solar cell element 3 to face south at an angle.

In this case, electrical power generation extremely decreases by the elevation angle of the sun according to time. However, in the solar cell module in accordance with the present invention, it becomes possible to suppress the change in the electrical power generation due to the direction of installation or time, since solar light incident from the rear surface member 5 side can be received and utilized for the power generation, decreasing the adverse effect due to the elevation angle of the sun.

Thereby, the solar light received from both surfaces of the solar cell module can be effectively contributed for the power generation with a simple method.

Since the solar cell module in regard to the present invention is less affected by the adverse effect of the surrounding environment, its installation locations vary greatly. The solar cell module can effectively exert its effects, at any given place where the solar cell module is installed, for example a sound abatement shield, a fall prevention fence, or a road sign which are set up at a roadside, an illuminating lamp or a monument which are set up at a park or the like, a wall surface or a roof of a building, a roof of a house, or on the ground.

Parenthetically, the solar cell module as per explained above comprises a first solar cell element group 8a and a second solar cell element group 8b, and can effectively contribute the light incident to each solar cell element group for power generation. However, it is extremely a rare case in which a light of the same illuminance incident on both solar cell element groups. For example, when the solar cell module is installed so that its surface faces in an east-west direction, the amount of insolation of the surface facing east in the morning, and the amount of insolation of the surface facing west in the afternoon respectively increases in comparison to the other surface. Hence, such solar cell module cannot obtain the same electrical power generation at the same time on both sides of the solar cell module.

Generally, a solar cell module establishes the required number of modules according to the needed voltage except when used alone, then connects such number of solar cell modules in series for connecting to an inverter so as to convert direct-current power to alternating-current power.

However, in a case of the solar cell module in accordance with the present invention, a loss in the power output would occur due to the difference of optimal operation current values when two solar cell elements are connected in series, since the electrical power generation of the first solar cell element group 8a and the second solar cell element group 8b hardly ever becomes the same.

In such case, it is preferable to employ a connection in which the first solar cell element group 8a and the second solar cell element group 8b are insulated and the power output is extracted respectively. Thereby, the loss of the power output can be prevented.

Furthermore, in the solar cell module in accordance with the present invention as mentioned above, a material having translucency is preferable for the rear surface member 5 of the solar cell module. By such configuration, receiving a direct solar light from the rear surface becomes possible. Furthermore, a reflection light from the exterior of the solar cell module can be received from the rear surface side of the solar cell module, and the light can be utilized for power generation. For a material having translucency, materials such as PET or EVA, or a transparent glass plate or a rigid plastic can be used.

Furthermore, it is preferable that the intermediate member 7 is a material which reflects light. By such configuration, permeation of the light incident from both front and rear surfaces is prevented, enabling to reflect the light to the solar cell element side, thereby increasing the light reaching the solar cell element. Hence, it becomes possible to enhance the output characteristics of the solar cell element, and obtain a highly efficient solar cell module.

In regard to the material that reflects light, which is to be used as the intermediate member 7, a steel plate colored white or mirror-finished, a PVF sheet with alumina having high reflectivity evaporated thereon, or a laminated sheet which includes alumina can be used.

In view of the weight of the solar cell module, it is preferable to use a lightweight material, and a sheet-shaped member such as a PVF sheet is suitable.

Furthermore, when a hard material that can ensure the strength of the solar cell module such as a steel plate is used, the thickness of the front surface member 1 or the rear surface member 5 which are disposed at the exterior of the solar cell element of the solar cell module can be reduced, since the strength of the solar cell module that is conventionally ensured by the front surface member 1 can be ensured by the intermediate member 7.

Furthermore, it is possible to use a material having translucency for the intermediate member 7. By such configuration, it becomes possible to permeate the light incident on the solar cell module but yet did not contribute to the power generation between the solar cell elements, and when the solar cell module in accordance with the present invention is used as a window material for example, lighting becomes possible. Furthermore, it becomes possible to utilize a part of the light incident from the front surface member 1 side but yet did not contribute to the power generation of the first solar cell element group 8a for the power generation of the second solar cell element group 8b.

Likewise, it is obvious that it becomes possible to utilize the light incident from the rear surface member 5 side for the power generation of the first solar cell element group 8a.

It is possible to use PET, EVA, a glass plate, or a plastic as the material having translucency at this point. However, considering the weight of the solar cell module or attenuation of light within the module, it is preferable to select a lightweight and comparatively thin material, and in view of this, PET and EVA are suitable.

Furthermore, when a hard material such as glass or plastic used as the intermediate member 7, the thickness of the front surface member 1 or the rear surface member 5 which are disposed at the exterior of the solar cell element of the solar cell module can be reduced, since the strength of the solar cell module that is conventionally ensured by the front surface member 1 can be ensured by the intermediate member 7. Hence it becomes possible to increase the light reaching the solar cell element than before, enhancing the output characteristics of the solar cell module.

Furthermore, a material that reflects light can be utilized for the rear surface member 5. By such configuration, it becomes possible for the light incident from the front surface member 1 side but yet did not contribute to the power generation of the first solar cell element group 8a and permeated through the solar cell module is reflected at the rear surface member 5. Thereby a part of the light incident from the light receiving surface side of second solar cell element group 8b enables to enhance power generating efficiency.

It is possible to use a steel plate colored white or mirror-finished, a PVA sheet with alumina having high reflectivity evaporated onto it, or a laminated sheet which includes alumina can be used as the material that reflects light at this point.

Furthermore, as shown in FIG. 2, when unevenness is provided to the rear surface member having reflectiveness, the light can be effectively contained by multiple reflection or the like, thus enhancing the power generating efficiency more effectively.

Although the solar cell module in accordance with the present invention has been described as mentioned above, it is to be understood that such disclosure is not to be interpreted as limiting, and various alterations and modifications may be applied without departing from scope of the present invention.

For example, a thermoplastic resin sheet such as EVA may be provided in advance between the intermediate member 7 and the solar cell element group 8 (the first solar cell element group 8a, and the second solar cell element group 8b). Thereby, when the solar cell module is heated with a laminator, adhesiveness between the intermediate member 7 and the solar cell element group 8 further increases, enabling to obtain a highly reliable solar cell module. Furthermore, these sheets serve as a cushioning material, preventing fracture of the solar cell element. It is particularly effective when a material that has no thermoplasticity nor adhesiveness such as glass or plastic is used as the intermediate member 7.

Furthermore, although an example in which the first solar cell element group 8a and the second solar cell element group 8b used a solar cell element having approximately same characteristics is described in the above-mentioned description, the present invention is not limited to such example, and for example, a solar cell element 3 in which optimal operation wavelength differs can be used. Such solar cell module that is configured so as to use solar cell element groups which differ in optimal operation wavelength, for example in a case where the solar cell module is used as a window of a house, enables the first solar cell element group 8a to use a solar cell element 3 which operates most suitably by solar light, and enables the second solar cell element group 8b to use a solar cell element 3 which operates most suitably by indoor light, achieving a configuration that is extremely adapted to the installation environment. In regard to such configuration, and a bulk type polycrystalline silicon or a single crystal silicon solar cell may be used as the first solar cell element group 8a, and an amorphous silicon solar cell may be used as the second solar cell element group 8b.

Furthermore, in FIG. 1 and FIG. 2 used for the above-mentioned description, the disposition of the solar cell elements in the first solar cell element group 8a and the second solar cell element group 8b are drawn so that the solar cell elements are disposed symmetrically centering on the intermediate member 7, but disposition of each solar cell element may be shifted.

In a case where a material having translucency is used to both the intermediate member 7 and the rear surface member 5, utilizing light that permeated through the solar cell module to the exterior, for example absorbing the light indoors, and using the solar cell module in accordance with the present invention as a so-called light through module, it is preferable for the solar cell elements to be disposed symmetrically centering on the intermediate member 7, and in a case where there is a need to decrease the light that permeates through the solar cell module to the exterior, it needs only to dispose the solar cell element 3 of the second solar cell element group 8b so as to infill the gap of the first solar cell element group 8a.

Furthermore, the number or size of solar cell element 3 to be used for the first solar cell element group 8a does not necessarily need to be the same as the solar cell element 3 to be used for the second solar cell element group 8b.

In addition, even a solar cell module which is configured as such can obtain the effect of the present invention, wherein a material having translucency is used for the intermediate member 7 and the rear surface member 5, means to reflect light to the exterior of the rear surface member 5 is provided, the light that goes through the solar cell module is reflected by this reflecting means, and a part of that light is made to be received at the second solar cell element 8b provided on the rear side.

Furthermore, although an example in which a single crystal solar cell element that is formed by melting and recrystallizing a silicon, or a polycrystalline solar cell element is used as the solar cell element is described in the above-mentioned description, the present invention is not limited to such example, and an amorphous silicon solar cell element that evaporates a silicon onto the substrate in an amorphous state, or a solar cell element that uses other compound semiconductor element may be used.

Subsequently, a photovoltaic device that uses the solar cell module as mentioned above, extracts the maximum generated output from the respective solar cell element groups 8a and 8b, and can conduct the most suitable operation control will be described (cf. US 2004-0211459A).

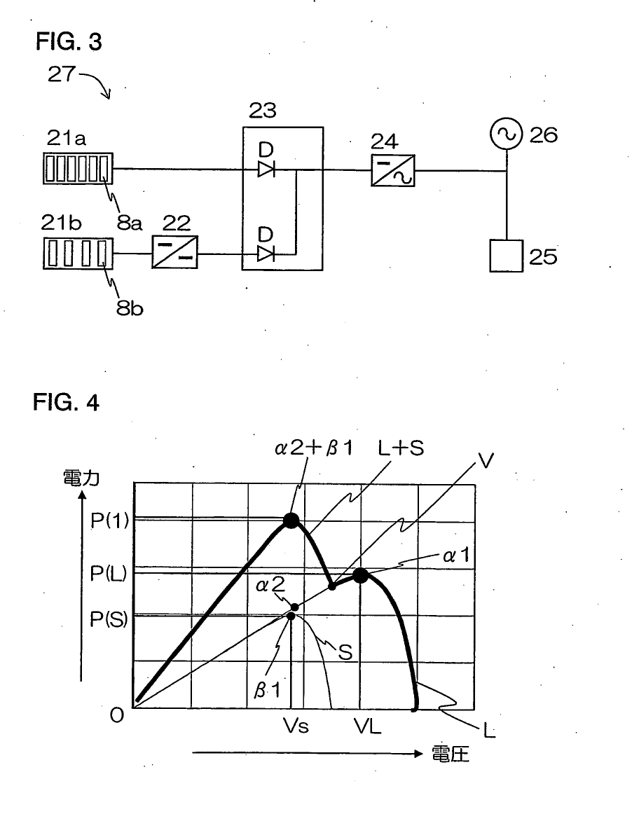

A block diagram of a photovoltaic device 27 in accordance with an embodiment of the present invention is shown in FIG. 3. This photovoltaic device 27 has a following configuration. Initially, a first solar cell string 21a in which the first solar cell element group 8a in accordance with the present invention as mentioned above is connected, and a second solar cell string 21b in which the second solar cell element group 8b in accordance with the present invention as mentioned above is connected. These solar cell strings 21a and 21b are configured so as to be connected in parallel after each string is connected to a backflow prevention diode D which is included in a connection box 23, and to provide the generated output of each solar cell string 21a and 21b to an alternating-current load 25 which is a load, or to a commercial electric power system 26 through a power conditioner 24 which is a power conversion means. Parenthetically, the second solar cell string 21b is connected in parallel between the first solar cell string 21a and the power conditioner 24 through the voltage adjustment means 22.

Parenthetically, a solar cell string is as follows. Initially, a plurality of solar cell elements are for example connected in series to obtain a high voltage, in order to obtain an output voltage that suits the load for providing electric power, since a single solar cell element has only about 0.5 V of output voltage. Such plurality of solar cell elements that are connected in series and made into a solar cell module, or a connected plurality of solar cell element groups which a plurality of solar cell elements are assembled, is denoted as a solar cell string. As described above, the first solar cell string 21a in accordance with the present invention is configured by connecting the first solar cell element group 8a, and the second solar cell string 21b is configured by connecting the second solar cell element group 8b which is disposed on the opposite side to the first solar cell element group 8a by sandwiching the solar cell module disposed between the two solar cell element groups. Therefore, the first solar cell string 21a and the second solar cell string 21b mutually differs in generating capacity in many cases since insolation conditions mutually differs, and in addition, such magnitude correlation of generation capacity also differs due to the time. Furthermore, as described above, generating capacities, output voltages and the like mutually differs with the first solar cell element group 8a and the second solar cell element group 8b in a case where a solar cell elements that differs in optimal function wavelength are used.

The power conditioner 24 is a power conversion means for converting a direct current power that is output by each solar cell string 21a and 21b into an alternating current power, and adjusts the provided voltage so that the direct current power provided from each solar cell string becomes maximum. For example, the power conditioner 24 adjusts so that direct current voltage in which the direct current power provided from the first solar cell string 21a becomes maximum.

The connection box 23 connects the respective solar cell strings 21a and 21b in parallel, adds output power output from each solar cell strings 21a and 21b, and provides them to the power conditioner 24. Furthermore, the backflow prevention diode D is provided to each string so as to prevent the electric current from one solar cell string from a backflow to the other solar cell string. The backflow prevention diode D is disposed close to the string side than the connecting contact in the path that connects the strings in parallel.

The voltage adjustment means 22 is disposed in the path that electrically connects the second solar cell string 21b and the connection box 23, and disposed close to the second battery string 21b than the backflow prevention diode D. The voltage adjustment means 22 adjusts the provided direct current voltage so that the direct current power provided from the second solar cell string 21b becomes maximum, and raises the adjusted direct current voltage, and provides the raised voltage to the power conditioner 24 through the connection box 23.

In order to increase the electric current, it needs only to connect each solar cell string in parallel as described above. However, when strings that differ in output voltage are connected in parallel, maximum output power points locate at different points for each string as will be described below, hence the maximum output power as a system becomes unavailable. Consequently, it is preferable that the output voltage of the respective solar cell strings that are connected in parallel are made uniform by the voltage adjustment means 22.

Furthermore, in regard to the solar cell string, it is preferable that a predetermined standard number of solar cell elements are to be connected so that its voltage and electric current can be efficiently converted to electric power by the power conditioner 24. Parenthetically, according to the embodiment of the present invention, the solar cell elements are connected in series to configure the solar cell string, however, the solar cell elements may be connected in series or parallel to configure the solar cell string.

Generally, the output of each solar cell string is connected in parallel through the backflow prevention diode D in order to prevent electric current from the string having a high voltage from flowing into the string having a low voltage when the output voltage of one solar cell string falls. In a case where the output voltage of the second solar cell string 21b is lower than the first solar cell string 21a, the output power from the second solar cell string 21b is not added as the power output for lack of voltage when the second solar cell string 21b is connected to the first solar cell string 21a in parallel. Therefore, the output voltage of the second solar cell string 21b is raised by the voltage adjustment 22 to coincide with the output voltage of the first solar cell string 21a.

Furthermore, in the case where the output voltage of the second solar cell string 21b is higher than the first solar cell string 21a, the output voltage of the second solar cell string 21b is lowered to coincide with the output voltage of the first solar cell string 21a so as to prevent the output power from the first solar cell string 21a from not being added.

The voltage adjustment means have a step-up type, a step-down type, and a polarity inverse type, and a switching regulator which conducts a switching control that mainly uses an inductance and a capacitor is suitable.

The electric power which is accumulated as such is provided to the power conditioner 24, and the power conditioner 24 converts the direct current power to an alternating current power, converting to the voltage and electric current phase synchronized to the alternating current load 25 so that it becomes usable in the alternating load 25 such as an electric lamp or a motor device.

Apart from the electric supply which can be used only in the alternating current load 25 as an independent power supply, when the electric current is converted, for example, a combination of a security device and the like with the power conversion mechanism may be connected to the commercial electric power system 26 that is supplied from an electric company so as to purchase and sell electricity.

Parenthetically, in FIG. 3, although only a single first solar cell string 21a and a single second solar cell string 21b are shown, it is to be understood that more solar cell strings can further be included. However, in regard to this photovoltaic device 27, in a case where a plurality of the first solar cell strings 21a are included, it is preferable that the number of solar cell elements connected in series for each string be the same or an approximate value, for example, satisfying a tolerance of approximately ±10%. Parenthetically, in a case where a plurality of the second solar cell strings 21b are connected, the number of solar cell elements connected in series for each second solar cell string does not need to be the same.

FIG. 4 is a graph indicating the output characteristics of the first and second solar cell strings.

In FIG. 4, conditions of output powers when two solar cell strings 21a and 21b that differs in generating capacity are connected in parallel without the voltage adjustment means 22 in accordance with the present invention is explained.

The output power curve L in the graph denotes an output power from the first solar cell string 21a, and the output power curve S denotes an output power from the second solar cell string 21b. When the output power curve L and the output power curve S are added due to parallel connection, it becomes an output power curve (L+S). The maximum power point (α2+β1), which is the output power point where the power output is maximum on the moment the respective solar cell strings are generating a power, is shown in FIG. 4.

However, the electric power value P(1) at the maximum power point (α2+β1) when such first solar cell string 21a and second solar cell string 21b that differ in voltage are connected in parallel is only be approximately twice the value of electric power value P(S) at the maximum power point β1 of the second solar cell string 21b. Therefore, the electric power value P(1) is not the sum with the electric power value P(L) at the maximum power point α1 of the first solar cell string 21a (α1+β1) but the loss of the electric power of (α2−α1).

Furthermore, a second power output point α1 appears in the lower slope of the maximum power point (α2+β1) on the output power curve (L+S), and since a valley of the electric power V occurs between the maximum power point (α2+β1) and the power output point α1, the power conditioner 24 misjudges the valley V as the slope on the opposite side of the maximum power point regarding an MPPT control (Maximum Power Point Tracking), which will be described below, and conducts a tracking movement assuming that the power output point α1 is the maximum power point. Hence the conventional photovoltaic device not only unable to obtain the maximum power output, but there will a problem in which only the electric power P of the first battery string 21a alone can be utilized in a case where the operating voltage is determined from the maximum power point α1 of the output power curve L.

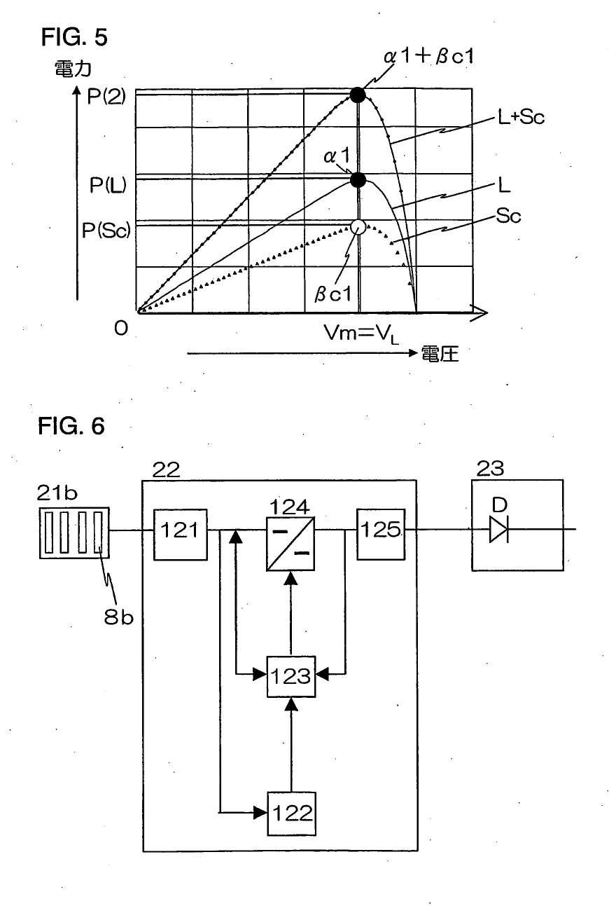

Meanwhile, an output power curve in regard to the photovoltaic device 27 in accordance with the present invention will be described with reference to FIG. 5.

The output power curve L denotes an output power from the first solar cell string 21a, and the output power curve Sc denotes an output power after the output voltage from the second solar cell string 21b is raised by the voltage adjustment means 22.

As can be understood from the graph, voltage value Vm of the maximum power point βc1 of the second solar cell string 21b that is raised by the voltage adjustment means 22 matches the optimum voltage value V_{L} of the maximum power point α1 of the first solar cell string 21a.

Therefore, in a case where the respective solar cell strings 21a and 21b are connected in parallel, the maximum output power curve (L+Sc) in which the maximum values of the output power curve L and the output power curve Sc are added can be obtained when the output power from the first solar cell strings 21a indicated as the output power curve L and the output power from the second solar cell string 21b indicated as the output power curve Sc are added.

Thereby the second power output point does not appear in the lower slope of the maximum power point (α2+βc1), and the electric power value P(2) at the maximum power point (α2+βc1) when the respective solar cell strings 21 and 21b are connected in parallel can be assumed as the sum of the electric power value P(Sc) of the second solar cell string 21b and the electric power value P(L) at the output power point α1 of the first solar cell string 21a. Furthermore, it becomes possible for the power conditioner 4 to easily detect the maximum power point (α1+βc1).

Hence, in regard to the photovoltaic device 27 in accordance with the present invention, by disposing the voltage adjustment means 22 between the first solar cell string 21a and the backflow prevention diode D, a larger maximum output power value P(2) can be obtained in comparison to a case in which the solar cell strings that differ in its output voltage are connected simply in parallel, and such maximum output power can be provided to the power conditioner 24. Furthermore, it is preferable that such voltage adjustment means is easily detachable in regard to the path that electrically connects the second solar cell string 21b and the connection box 23. By such configuration, the voltage adjustment means 22 can be detached, for example, when the second solar cell string 21b can be changed to the first solar cell string 21a due to addition of the solar cell modules.

Subsequently, the voltage adjustment means 22 is described.

FIG. 6 is a block diagram showing the details of a voltage adjustment method 22. As shown in FIG. 6, the voltage adjustment means 22 comprises an input EMI (electromagnetic interference) filter 121 for protecting the circuit from a surge voltage from an external source, an output EMI filter 125, a power supply part 122 for obtaining a power supply to drive the entire voltage adjustment means from the output power of the second solar cell string 21b, a control part 123 for detecting the voltage conditions of both the input side and the output side and detecting the maximum power point β1 of the second solar cell string 21b, and a step-up voltage part 24 which is controlled by the control part 123 and raises the direct current voltage that is output from the second solar cell string 21b.

A step-up voltage control operation of this voltage adjustment means 22 is described.

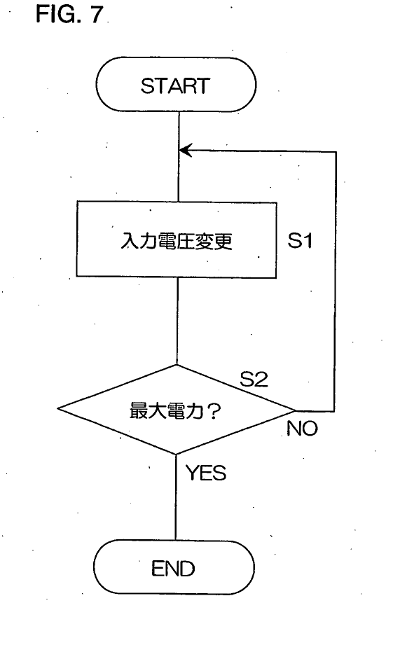

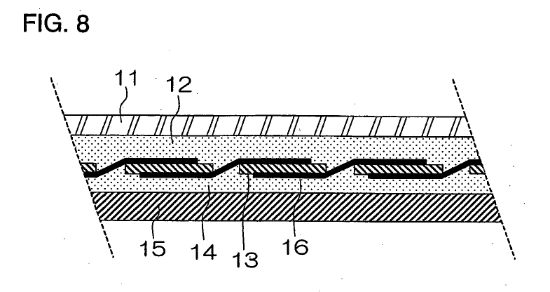

FIG. 7 is a flow chart showing the step-up voltage control operation of the control part 123 in FIG. 6.

Initially, a voltage for driving is provided to the control part 123 at the start of operation, and the step-up voltage part 124 becomes controllable. The step-up voltage control operation starts in Step 1. In Step 1, the control part 123 conducts a Maximum Power Point Tracking control. More specifically, the control part 123 changes a step-up voltage ratio and increases and decreases the direct current output from the second solar cell string 21b to change its direct current voltage. Then the operation proceeds to Step 2. In Step 2, the direct current power that are output from the second solar cell string 21b during the change are sequentially measured. Then, the operating point in which the direct current becomes maximum. More specifically, the optimal voltage value Vs in which the electric power output from the second solar cell string 21b becomes maximum is detected, as shown in FIG. 4. Then the operation ends.

In regard to the solar cell string, a short-circuit current changes with the change in the amount of insolation, and an open-circuit voltage changes with the change in temperature. Therefore, since the direct current power that is output from the solar cell string changes hourly, there is a need to continuously detect an operating point that becomes the maximum electric power. Such operation is conducted for example as follows.

The control part 123 has an arithmetic circuit (not shown) implemented by integrated circuits and the like. The arithmetic circuit detects the direct current voltage and the direct current that are output and provided from the second solar cell string 21b, and performs an arithmetical operation on the direct current power. Subsequently, the arithmetic circuit changes the direct current voltage provided from the second solar cell string 21b for a predetermined voltage value that is assumed as worth a single step, and performs the arithmetical operation again on the direct current power at that time. For example, the arithmetic circuit is set so that a minute output current is provided from the second solar cell string 21b at the start of detection. The arithmetic circuit compares the present direct current power and the former direct current power, and when the present direct current power is increasing in comparison to the former direct current power, the arithmetic circuit decreases the direct current voltage provided by the second solar cell string 21b so that the present direct current voltage decreases still another one step's worth. Furthermore, when the present direct current power is decreasing in comparison to the former direct current power, the arithmetic circuit increases the direct current voltage provided by the second solar cell string 21b so that the present direct current voltage increases still another one step's worth.

Such operation is repeatedly conducted, automatically detecting the voltage and electric current in which the provided direct current power becomes maximum. Since such operation is continuously conducted, the electric power can be automatically tracked so as to operate the electric power provided from the second solar cell string 21b at the maximum power point, even when solar light is shielded by a cloud or the like, or when weather changes. The optimal voltage value Vs in which electric power provided from the second battery string 21b is determined in such manner.

A load of the voltage adjustment 22 is adjusted to a voltage in which the electric power provided from the first solar cell string 21a becomes maximum by the power conditioner 24. For example, in a case where the voltage provided from the first solar cell string 21a to the power conditioner 24 is set at 300 V, a voltage that is decreased to 300 V is provided to the power conditioner 24 from the voltage adjustment means 22, even when the voltage output from the voltage adjustment means 22 is 300 V or over.

The direct current voltage provided to the voltage adjustment means 22 from the second solar cell string 21b also changes due to such decrease of the voltage output from voltage adjustment means 22. The voltage adjustment 22 changes and resets the direct current voltage provided from the second solar cell string 21b by conducting an MPPT control so that the maximum electric power is provided based on this altered direct current voltage. Hence, the voltage adjustment means 22 can set the input voltage provided from the second solar cell string 21b so that the maximum electric power is provided from the second solar cell string 21b after the voltage is output by the converted voltage value Vm of the power conditioner 24 in advance.

Parenthetically, the voltage adjustment means 22 shown in the example is described as a case in a step-up voltage type. However, it is to be understood that a desired result can be obtained by a similar control even when a step-down voltage type or a polarity inverse type is employed. Furthermore, such voltage adjustment means 22 is merely one example of the present invention, and other configurations is also adequate when there is a similar function as described above.

For example, a transformerless type is used in regard to the power conditioner 24, and implemented by including a boost chopper circuit, a PMW inverter circuit and a control circuit. A direct current power provided from the first solar cell string 21a and the direct current power provided from the voltage adjustment means 22 are added at the connection box 23. That total electric power is provided to the power conditioner 24. A direct current voltage is provided to the boost chopper circuit from the connection box 23, and the provided direct current voltage is raised, then provided to the inverter circuit. The inverter circuit converts the provided direct current voltage to an alternating current voltage, and outputs the converted alternating current voltage. Furthermore, the control circuit conducts a Maximum Power Point Tracking control, adjusting the output electric current that is output from the power conditioner 24 so that the converted voltage value Vm in which the electric power provided from the connection box 23 becomes maximum. Furthermore, the power conditioner 24 conducts a PWM control in regard to the inverter circuit so that the provided direct current power is converted to an alternating current power according to increases and decreases of the converted voltage value Vm. As a result, the output electric current output from the power conditioner is changed, and the operating point in which the electric power provided from the connection box 23 becomes maximum is detected.

Such power conditioner is merely one example of the present invention, and other configurations is also adequate in a case where the Maximum Power Point Tracking controls are conducted and there is a function that can convert the direct current into an alternating current.

Incidentally, in a case where a voltage is provided through the connection box 23 to the first solar cell string 21a before the second solar cell string 21b, the power conditioner 24 adjusts so that the optimal voltage value V_{L} of the first solar cell string 21a is provided to the power conditioner 24. More specifically, the converted voltage value Vm matches the optimal voltage value V_{L} of the first solar cell string 21a.

When a voltage is provided in this state from the second solar cell string 21b through the connection box 23, a direct current voltage which is raised so that the optimal voltage Vs of the second solar cell string 21b becomes equal to the converted voltage value Vm by the voltage adjustment means 22 is provided to the power conditioner 24. Since the converted voltage value Vm is equal to the optimal voltage value V_{L} of the first solar cell string 21a, the optimal voltage value V_{L} of the first solar cell string 21a and the optimal voltage value Vs of the second solar cell string 21b which are raised to the voltage of the first solar cell string 21a are both provided to the power conditioner 24. More specifically, the power conditioner 24 can convert the direct current power to the alternating current power at the maximum direct current power P(2) as shown in FIG. 5.

Hence, the voltage adjustment means 22 conducts the Maximum Power Point Tracking control which can detect and track the operating point which is the maximum power output of the solar cell at the moment with the control part 123, to increase the power generating efficiency, and operate at the maximum power point β1 of the connected second solar cell string 21b, thereby obtaining the maximum output power of the connected second solar cell string 21b.

Furthermore, the voltage of the output side of the voltage adjustment means 22 is free, or more specifically, needs no control of the output voltage, which becomes equal to the output voltage of the first solar cell string 21a, or the control voltage of power conditioner 24. The step-up voltage ratio which is a ratio of the input voltage that is determined in this matter and provided from the second solar cell string 21b and the output voltage provided to the power conditioner 24 by raising that input voltage is automatically adjusted. More specifically, step-up of a voltage ratio at the time of installation is unnecessary, man-hour for installation can be reduced, and, can eliminate malfunction due to improper setting.

Parenthetically, in a case where the direction of installation for each solar cell string differs, a difference may occur to the operation point for obtaining the maximum power output for the respective solar cell strings due to the insolation conditions and temperature conditions in regard to the solar cell module configured by the solar cell strings. However, due to the Maximum Power Point Tracking control function of the voltage adjustment means 22, it becomes possible to coincide the maximum power point of the respective solar cell strings, and to obtain the true maximum output power for which operation becomes possible at that maximum power point. More specifically, the maximum electric power in which deviation does not exist can be obtained in regard to the output characteristics of the solar cell, a higher output power can be obtained while reducing loss of the output power.

Furthermore, it may be configured so that energy from the second solar cell string 21b that is connected to the voltage adjustment means 22 itself be used as a driving energy, and thus the voltage adjustment means 22 operates simultaneously with the second solar cell string 21b only while daytime when the second solar cell string 21b operates, and automatically stops at nighttime to prevent unnecessary power consumption.

The time of feedback in regard to each control of the power conditioner 24 and the voltage adjustment means 22 can be arbitrarily established, for example, programmed to be from several seconds to several tens of seconds. Thereby, the direct current power can be converted to an alternating current power at the maximum electric power of each solar cell string, even when the amount of insolation or temperature is changed.

Furthermore, in a case where a large amount of electric power is needed, the power conditioner 24 may be connected in parallel. For example, in a case where the maximum power output of the power conditioner 24 is 5 kW, in order to obtain an output voltage of 6 kW, a first power conditioner 24 that can output 5 kW of electric power and a second power conditioner 24 that can output 1 kW of electric power are connected in parallel. Or, a first power conditioner 24 that can output 3 kW of electric power and a second power conditioner 24 that can output 3 kW of electric power may be connected in parallel.

The power conditioner 24 has a function for interconnecting the output voltage and its phase which are adjusted to the optimal power output to coincide with the commercial power source. In a case where respective power conditioners are connected in parallel, and when solar cell strings each having a different generating capacity are connected to the input side of the power conditioner 24, the generating capacity can further be enhanced by providing the voltage adjustment means 22.

1. A solar cell module, comprising;
a front surface member having translucency,
a rear surface member,
an intermediate member formed of an insulator disposed between said front surface member and said rear surface member,
a first solar cell element group in which a plurality of solar cell elements are electrically connected, disposed between said front surface member and said intermediate member with its light receiving surface facing said front surface member,
and a second solar cell element group in which a plurality of solar cell elements are electrically connected, disposed between said rear surface member and said intermediate member with its light receiving surface facing said rear surface member.

2. A solar cell module in accordance with claim 1, wherein said plurality of solar cell elements are connected in series in both said first solar cell element group and said second solar cell element group, and both solar cell element groups are electrically insulated through said intermediate member.

3. A solar cell module in accordance with claim 1, wherein said rear surface member is a material having translucency.

4. A solar cell module in accordance with claim 3, wherein said intermediate member is a material that reflects light.

5. A solar cell module in accordance with claim 1, wherein said intermediate member is a material having translucency.

6. A solar cell module in accordance with claim 1, wherein said rear surface member is a material that reflects light.

7. A solar cell module in accordance with claim 6, wherein convexoconcave is provided in said rear surface member.

8. A solar cell module in accordance with claim 5, wherein a solar cell element comprising said first solar cell element group and a solar cell element comprising said second solar cell element group are disposed symmetrically with said intermediate member as the reference position.

9. A solar cell module in accordance with claim 5, wherein a solar cell element comprising said first solar cell element group and a solar cell element comprising said second solar cell element group are disposed unsymmetrically with said intermediate member as the reference position.

10. A photovoltaic device using a solar cell module in accordance with any one of claims 1 to 9, comprising;
a first solar cell string having connected said first solar cell element group, and a second solar cell string having connected said second solar cell element group,
a power conversion means for converting direct-current power to alternating-current power as well as controlling so that direct-current power is output at the maximum power point of these first and second solar cell string,
and a voltage adjustment means for adjusting direct-current voltage that is output from said second solar cell string and supplying the voltage between said first solar cell string and said voltage adjustment means,
wherein said voltage adjustment means adjusts the output voltage of said second solar cell string so that it coincides with the output voltage of said first solar cell string.

11. A photovoltaic device in accordance with claim 10, wherein said voltage adjustment means adjusts the direct-current voltage that is output from said second solar cell string based on the voltage which is to be the maximum electric power of said second solar cell string to coincide with the output voltage of said first solar cell string.
